(19) United States
(12) Patent Application Publication
(10) Pub. No.: US 2025/0385666 A1
(43) Pub. Date: Dec. 18, 2025

(54) SEMICONDUCTOR DEVICE

(71) Applicant: FUJI ELECTRIC CO., LTD., Kawasaki-shi (JP)

(72) Inventor: Masanari FUJII, Matsumoto-city (JP)

(73) Assignee: FUJI ELECTRIC CO., LTD., Kawasaki-shi (JP)

(21) Appl. No.: 19/192,908

(22) Filed: Apr. 29, 2025

(30) Foreign Application Priority Data
Jun. 13, 2024 (JP) 2024-095696

(51) Int. Cl. H03K 17/082; H03K 17/16

(52) U.S. Cl. CPC H03K 17/0828; H03K 17/168

(57) ABSTRACT

A semiconductor device capable of suppressing variations in responsiveness of a switching element even when the driving capability to drive the switching element is changed. The semiconductor device includes: an IGBT; a state detection section configured to detect the operation state of the IGBT; a switching time adjustment section configured to adjust a switching time of the IGBT according to the operation state detected in the state detection section; and a drive current adjustment section configured to adjust a drive current driving the IGBT according to the operation state detected in the state detection section.

### CROSS-REFERENCE TO RELATED APPLICATIONS

This application claims the benefit of priority under 35 USC 119 based on Japanese Patent Application No. 2024-095696, filed on Jun. 13, 2024, the disclosure of which is incorporated by reference herein in its entirety.

### TECHNICAL FIELD

The present invention relates to a semiconductor device including a switching element.

### BACKGROUND ART

PTLS 1 to 3 disclose technologies that change the driving capability to drive a switching element according to a load current that the switching element supplies to a load when the switching element is turned on or turned off.

### CITATION LIST

### Patent Literatures

PTL 1: JP 2016-158361 A
PTL 2: JP 2020-136874 A
PTL 3: WO 2017/150036 A1

### SUMMARY OF INVENTION

### Technical Problem

When the driving capability of the switching element is changed according to the load current, the driving capability of the switching element is set to be higher the larger the load current, and therefore the voltage variation ratio (dv/dt) of the switching element in turn-on or in turn-off becomes high. Thus, the changing driving capability of the switching element according to the load current varies the responsiveness of the switching element, which poses a problem of increasing the possibility that the operation of the device having the switching element becomes unstable.

It is an object of the present invention to provide a semiconductor device capable of suppressing the variations in responsiveness of the switching element even when the driving capability to drive the switching element is changed.

### Solution to Problem

To achieve the above-described object, a semiconductor device according to one aspect of the present invention includes: a switching element; a state detection section configured to detect the operation state of the switching element; a switching time adjustment section configured to adjust a switching time of the switching element according to the operation state detected in the state detection section; and a drive current adjustment section configured to adjust a drive current driving the switching element according to the operation state detected in the state detection section.

### Advantageous Effects of Invention

According to one aspect of the present invention, the variations in responsiveness of the switching element can be suppressed even when the driving capability to drive the switching element is changed.

### BRIEF DESCRIPTION OF DRAWINGS

FIG. 1 is a block diagram illustrating one example of the schematic configuration of a semiconductor device according to a first embodiment of the present invention;

FIG. 2 is a view illustrating the relation between a load current and a voltage variation ratio of a switching element in a conventional technology;

FIG. 3 is a view illustrating the relation between a load current and a turn-on time of the switching element in the conventional technology;

FIG. 4 is a view for explaining the semiconductor device according to the first embodiment of the present invention, and is a timing chart schematically illustrating one example of an operation waveform in turn-on of a switching element;

FIG. 5 is a block diagram (No. 1) illustrating one example of the schematic configuration of a semiconductor device according to a second embodiment of the present invention;

FIG. 6 is a block diagram (No. 2) illustrating one example of the schematic configuration of the semiconductor device according to the second embodiment of the present invention;

FIG. 7 is a view for explaining the semiconductor device according to the second embodiment of the present invention, and is a timing chart schematically illustrating one example of an operation waveform in turn-on of a switching element;

FIG. 8 is a block diagram illustrating one example of the schematic configuration of a semiconductor device according to a third embodiment of the present invention;

FIG. 9 is a block diagram (No. 1) illustrating one example of the schematic configuration of a semiconductor device according to a fourth embodiment of the present invention;

FIG. 10 is a block diagram (No. 2) illustrating one example of the schematic configuration of the semiconductor device according to the fourth embodiment of the present invention; and

FIG. 11 is a view for explaining the semiconductor device according to the fourth embodiment of the present invention, and is a timing chart schematically illustrating an input signal and an output signal output from a switching time adjustment section.

### DESCRIPTION OF EMBODIMENTS

Embodiments of the present invention exemplify devices or methods for embodying the technical idea of the present invention. The technical idea of the present invention does not specify the materials, shapes, structures, arrangement, and the like of constituent components to the materials, shapes, structures, arrangement, and the like described below. The technical idea of the present invention can be variously altered in the technical scope defined by the claims.

### First Embodiment

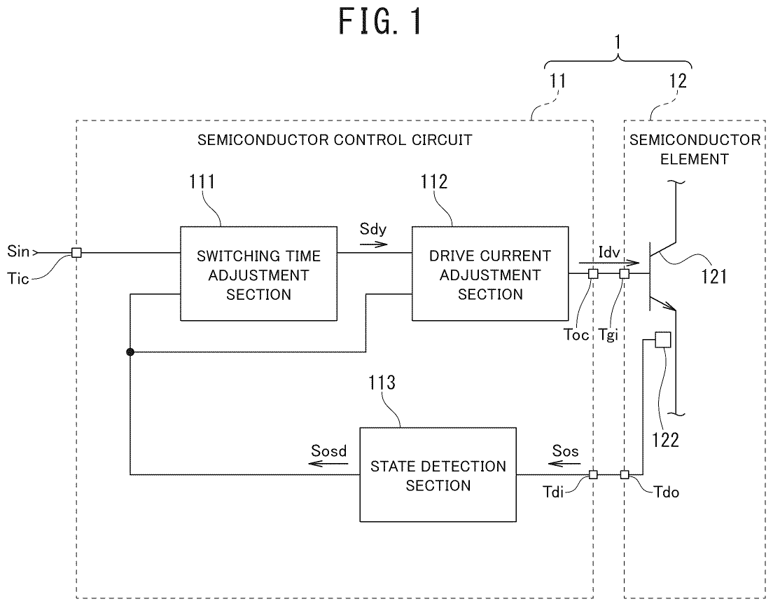

A semiconductor device according to a first embodiment of the present invention is described using FIGS. 1 to 4. Semiconductor devices according to this embodiment and embodiments described below are, for example, applicable to an intelligent power module (IPM) where a semiconductor chip having a power semiconductor element for power conversion (e. g., insulated gate bipolar transistor) and an integrated circuit for driving/protection functions that drives and protects the semiconductor chip are integrated in a single package. Hereinafter, the “Insulated Gate Bipolar Transistor” is sometimes abbreviated as “IGBT”.

### 1-1. Configuration of Semiconductor Device:

The schematic configuration of the semiconductor device according to this embodiment is described using FIG. 1. FIG. 1 is a block diagram illustrating one example of the schematic configuration of a semiconductor device 1 according to this embodiment.

As illustrated in FIG. 1, the semiconductor device 1 includes a semiconductor control circuit 11 and a semiconductor element 12. The semiconductor element 12 has an IGBT 121 and a state sensing element 122. The semiconductor element 12 may have a freewheeling diode connected in reverse parallel to the IGBT 121. The semiconductor element 12 contains, for example, a semiconductor chip where the IGBT 121 and the state sensing element 122 are formed.

Thus, the semiconductor device 1 includes the IGBT 121 (one example of the switching element). The operation state of the IGBT 121 includes, for example, a state in which how much current the IGBT 121 supplies to a load device (not illustrated) to be driven or a state in which at what temperature the IGBT 121 is operating. Accordingly, the state sensing element 122 may be, for example, a current sensing element sensing a current flowing to the IGBT 121 or a temperature sensing element sensing the temperature of the IGBT 121.

The load device is connected to an emitter of the IGBT 121 when the semiconductor device 1 is, for example, a power converter and the IGBT 121 constitutes an upper arm of the power converter. On the other hand, the load device is connected to a collector of the IGBT 121 when the IGBT 121 constitutes a lower arm of the power converter. The IGBT 121 has a gate connected to a gate input terminal Tgi provided in the semiconductor element 12. The state sensing element 122 has an output terminal connected to a sensing terminal Tdo provided in the semiconductor element 12.

As illustrated in FIG. 1, the semiconductor control circuit 11 has a switching time adjustment section 111, a drive current adjustment section 112, and a state detection section 113. Accordingly, the semiconductor device 1 includes the switching time adjustment section 111, the drive current adjustment section 112, and the state detection section 113. The semiconductor control circuit 11 is an integrated circuit for driving/protection functions that drives and protects the IGBT 121.

The state detection section 113 has an input terminal connected to a sensing signal input terminal Tdi provided in the semiconductor control circuit 11. The sensing signal input terminal Tdi is connected to the sensing terminal Tdo provided in the semiconductor element 12. Therefore, the state detection section 113 detects the operation state of the IGBT 121 using, for example, a sensing signal Sos input from the state sensing element 122. The state detection section 113 outputs a state detection signal Sosd detected using the sensing signal Sos.

The switching time adjustment section 111 has two input terminals, one of which is connected to a signal input terminal Tic provided in the semiconductor control circuit 11 and the other one of which is connected to an output terminal of the state detection section 113. The switching time adjustment section 111 adjusts a switching time of the IGBT 121 according to the operation state of the IGBT 121 detected in the state detection section 113. The switching time adjustment section 111 adjusts the switching time according to the signal level of the state detection signal Sosd input from the state detection section 113. Although details are described later, the switching time adjustment section 111 delays the output of an input signal Sin input via the signal input terminal Tic by a predetermined time when the state detection section 113 detects that the IGBT 121 is in a predetermined operation state. Thus, the switching time adjustment section 111 delays the input signal Sin by a predetermined time, so that the semiconductor device 1 can set the length of the switching time to be substantially the same irrespective of the operation state of the IGBT 121.

The drive current adjustment section 112 has two input terminals, one of which is connected to an output terminal of the switching time adjustment section 111 and the other one of which is connected to the output terminal of the state detection section 113. The drive current adjustment section 112 adjusts a drive current Idv driving the IGBT 121 according to the operation state of the IGBT 121 detected in the state detection section 113. The drive current adjustment section 112 adjusts the drive current Idv according to the signal level of the state detection signal Sosd input from the state detection section 113. The drive current adjustment section 112 adjusts the current amount of the drive current Idv to be large, for example, when the IGBT 121 is in the operation state in which the input signal Sin is delayed by a predetermined time in the switching time adjustment section 111. Thus, the semiconductor device 1 can suppress variations in responsiveness of the IGBT 121 irrespective of the current amount of the load current that the IGBT 121 supplies to the load device.

### 1-2. Operation of Semiconductor Device:

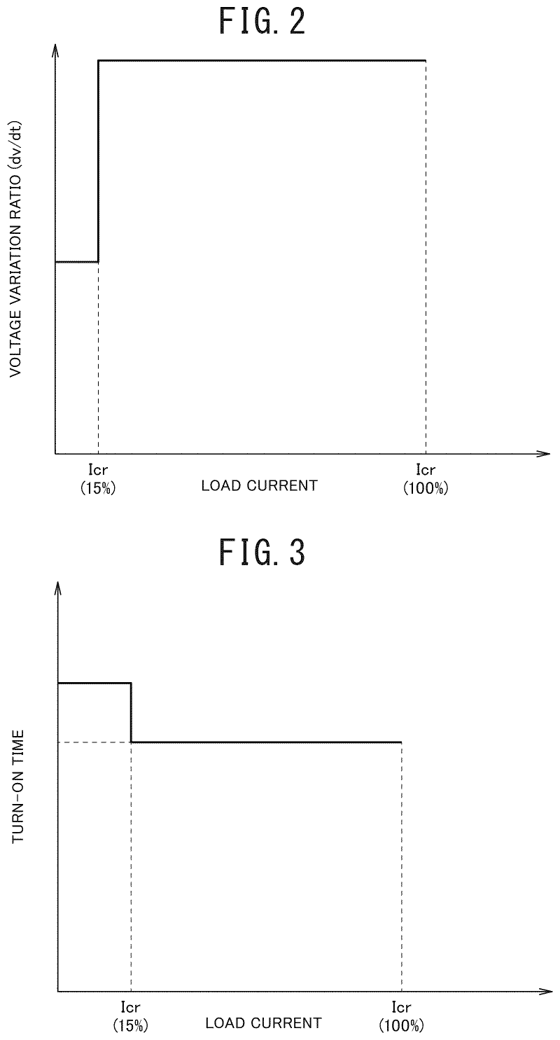

The operation of the semiconductor device 1 according to this embodiment is described using FIGS. 2 to 4 with reference to FIG. 1. In describing the operation of the semiconductor device 1, problems of conventional technologies are also described. In FIGS. 2 to 4, the operation state of the IGBT is described taking the current amount of a current flowing to the IGBT (i.e., load current that the IGBT supplies to a load) as an example.

FIG. 2 is a graph showing one example of the relation between the load current and the voltage variation ratio in turn-on in the IGBT. The horizontal axis of the graph illustrated in FIG. 2 indicates the load current and the vertical axis of the graph indicates the voltage variation ratio (dv/dt).

At the time of low current when the load current is, for example, 15% or less of a rated current Icr, the IGBT is driven with a driving capability lower than that at the time of normal current when the load current is, for example, larger than 15% and 100% or less of the rated current Icr. In this case, the voltage variation ratio of the IGBT is reduced at the time of low current as compared with that at the time of normal currents as illustrated in FIG. 2.

FIG. 3 is a graph showing one example of the relation between the load current and a turn-on time in the IGBT. The horizontal axis of the graph illustrated in FIG. 3 indicates the load current and the vertical axis of the graph indicates the turn-on time.

At the time of low current when the load current is, for example, 15% or less of the rated current Icr, the IGBT is driven with the driving capability lower than that at the time of normal current when the load current is, for example, larger than 15% and 100% or less of the rated current Icr. In this case, the turn-on time of the IGBT is longer at the time of low current than at the time of normal current as illustrated in FIG. 3.

Although not illustrated, when the IGBT is driven with the same driving capability as that at the time of normal current also at the time of low current, the voltage variation ratio of the IGBT sharply rises with a decrease in the load current at the time of low current. Therefore, when the IGBT is driven with the same driving capability as that at the time of normal current also at the time of low current, the immunity to noise signals of the IGBT decreases, which increases a possibility of a malfunction. Thus, as illustrated in FIG. 2, the IGBT is driven by setting the driving capability at the time of low current to be lower than that at the time of normal current, thereby reducing the possibility of a malfunction.

However, as described using FIG. 3, when the IGBT is driven by setting the driving capability at the time of low current to be lower than that at the time of normal current, the turn-on time is longer at the time of low current than at the time of normal current. When the turn-on time of the IGBT varies according to the load current, the responsiveness of the IGBT also varies, which increases a possibility that the operation of the device having the IGBT becomes unstable. Accordingly, it is difficult to achieve both the suppression of a malfunction caused by the reduced immunity to noise signals of the IGBT and the reduction in the operation instability caused by the variations in responsiveness of the IGBT.

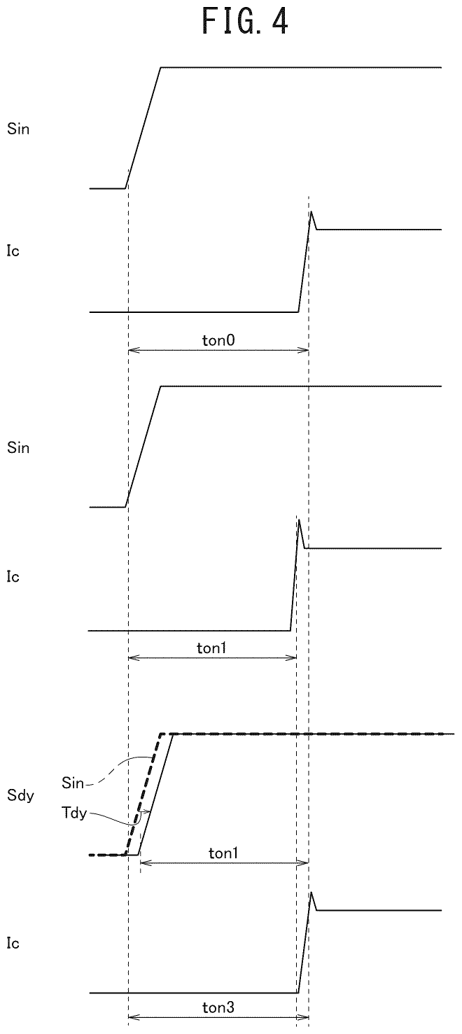

FIG. 4 is a timing chart schematically illustrating part of operation waveforms in turn-on of the IGBT 121 provided in the semiconductor device 1 according to this embodiment and a conventional IGBT. An upper part in FIG. 4 illustrates the operation waveforms of the IGBT 121 and the conventional IGBT. A middle part in FIG. 4 illustrates the operation waveforms of the conventional IGBT. A lower part in FIG. 4 illustrates the operation waveforms of the IGBT 121. “Sin” in FIG. 4 indicates an input signal input into the semiconductor control circuit 11 or a conventional semiconductor control circuit. “Ic” in FIG. 4 indicates a collector current (i.e., load current supplied to the load device) of the IGBT 121 or the conventional IGBT. “Sdy” in FIG. 4 indicates a delayed signal obtained by delaying an input signal.

Further, in the upper part in FIG. 4, the operation waveforms are illustrated when the IGBT 121 or the conventional IGBT is driven by a drive current at the time of low current described in FIGS. 2 and 3. In the middle part in FIG. 4, the operation waveforms are illustrated when the conventional IGBT is driven by the drive current at the time of normal current described in FIGS. 2 and 3. In the lower part in FIG. 4, the operation waveforms are illustrated when the switching time is adjusted, and the IGBT 121 is driven by the drive current at the time of normal current described in FIGS. 2 and 3. In the operation waveforms illustrated in the upper part to the lower part in FIG. 4, a direct-current voltage applied to the IGBT 121 or the conventional IGBT, an emitter-to-collector voltage in an off-state of the IGBT 121 or the conventional IGBT, the inductance value of the load, and the load current supplied to the load are made common. In the operation waveforms illustrated in the lower part in FIG. 4, the IGBT 121 is driven by a drive current having a current amount twice as large as the current amount in the upper part in FIG. 4.

As illustrated in the upper part and the middle part in FIG. 4, in the turn-on of the conventional IGBT, a switching time ton1 at the time of normal current becomes, for example, a 90% time of a switching time ton0 at the time of low current. The peak current in the overshoot of the collector current Ic is larger at the time of normal current than at the time of low current corresponding to the shorter switching time. Thus, the immunity to noise signals of the conventional IGBT decreases at the time of normal current as compared with that at the time of low current. In FIG. 4, the time from the input of the input signal Sin until the current value of the collector current Ic reaches 90% of the target value is defined as the switching time of the IGBT 121 or the conventional IGBT.

In the semiconductor device 1 according to this embodiment, the switching time adjustment section 111 (see FIG. 1) does not delay the output of the input signal Sin to the drive current adjustment section 112, for example, at the time of low current. Therefore, as illustrated in the upper part in FIG. 4, the switching time of the IGBT 121 in this embodiment becomes the switching time ton0 as with the conventional IGBT.

On the other hand, in the semiconductor device 1 according to this embodiment, the switching time adjustment section 111 delays the output of the input signal Sin to the drive current adjustment section 112, for example, at the time of normal current. Therefore, as illustrated in the lower part in FIG. 4, the switching time of the IGBT 121 in this embodiment is the switching time ton1, which has substantially the same length as that of the switching time of the conventional IGBT, based on the input timing of the delayed signal Sdy, which triggers the start of the supply of the drive current Idv. However, the delayed signal Sdy is a signal obtained by delaying the input signal Sin by a delay time Tdy in the switching time adjustment section 111. Therefore, a switching time ton3 of the IGBT 121 at the time of normal current has substantially the same length as that of the switching time ton of the IGBT 121 at the time of low current.

Thus, in the semiconductor device 1, the voltage variation ratio of the IGBT 121 is larger at the time of normal current than at the time of low current, which shortens the rise time from the start of the supply of the drive current Idv until the collector current Ic of the IGBT 121 reaches the target value. The semiconductor device 1 can adjust the delay time of the input signal Sin according to the voltage variation ratio of each load current of the IGBT 121 to offset the shortening of the rise time, thereby improving the immunity of the input signal Sin to noise signals and suppressing a variation in responsiveness of the IGBT 121.

The switching time of the IGBT 121 is delayed when the operating temperatures becomes higher. Therefore, the switching time adjustment section 111 is configured to be able to adjust the switching time such that a delay time becomes shorter the higher the operating temperature becomes when the operation state of the IGBT 121 is the operating temperature.

As described above, the semiconductor device 1 according to this embodiment includes the IGBT 121, the state detection section 113 detecting the operation state of the IGBT 121, the switching time adjustment section 111 adjusting the switching time of the IGBT 121 according to the operation state detected in the state detection section 113, and the drive current adjustment section 112 adjusting the drive current Idv driving the IGBT 121 according to the operation state detected in the state detection section 113.

The semiconductor device 1 has such a configuration, and therefore can suppress the variations in responsiveness of the switching element even when the driving capability to drive the switching element is changed.

### Second Embodiment

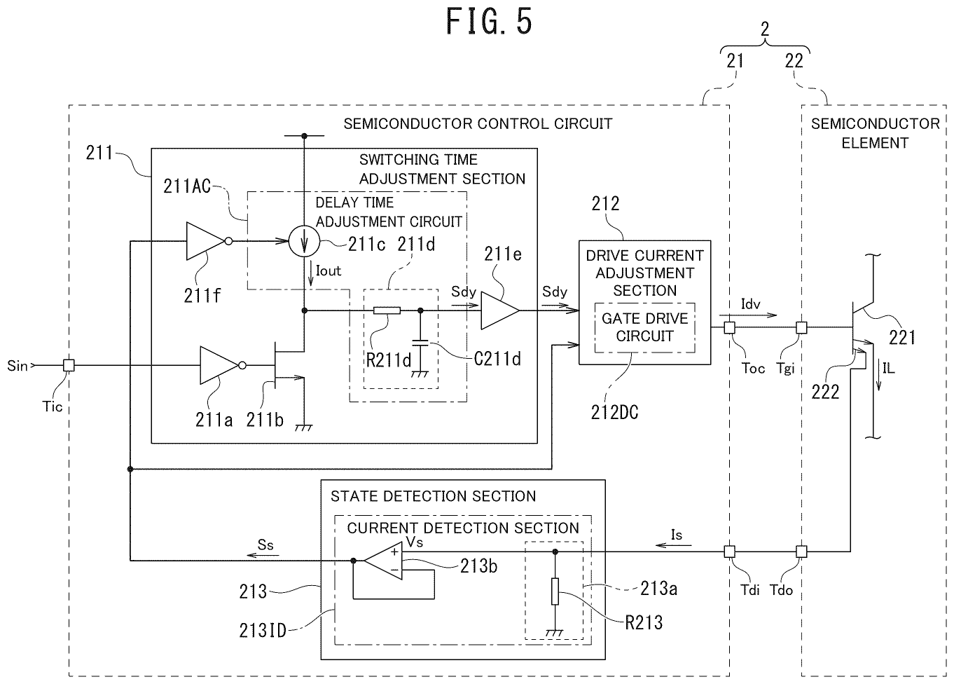

A semiconductor device according to a second embodiment of the present invention is described using FIGS. 5 to 7.

### 2-1. Configuration of Semiconductor Device:

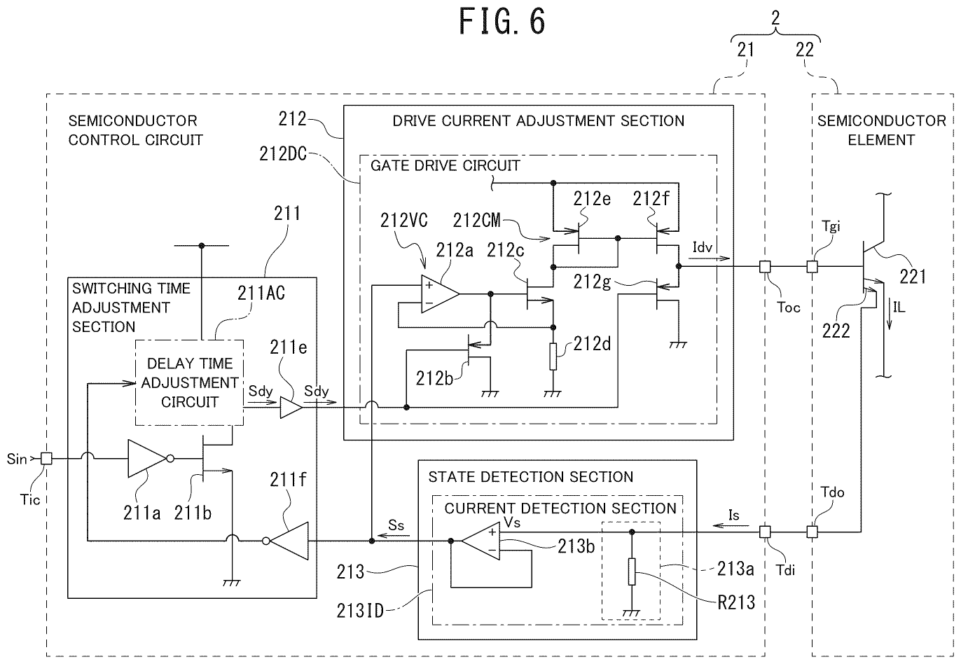

The schematic configuration of a semiconductor device 2 according to this embodiment is described using FIGS. 5 and 6. FIGS. 5 and 6 are block diagrams illustrating one example of the schematic configuration of the semiconductor device 2 according to this embodiment. FIG. 5 does not illustrate the specific configuration of a drive current adjustment section 212 provided in the semiconductor device 2. FIG. 6 does not illustrate the specific configuration of a delay time adjustment circuit 211AC provided in the semiconductor device 2. For the semiconductor device 2 according to this embodiment, the same reference sings are used for constituent elements exhibiting the same operations and functions as those of the constituent elements in the semiconductor device 1 according to the first embodiment above, and descriptions thereof are omitted.

As illustrated in FIGS. 5 and 6, the semiconductor device 2 according to this embodiment includes a semiconductor control circuit 21 and a semiconductor element 22. The semiconductor element 22 has an IGBT 221 and a current sensing element 222. Accordingly, the semiconductor device 2 includes the IGBT 221 (one example of the switching element) and the current sensing element 222. The current sensing element 222 senses a sensing current Is for detecting a load current IL that the IGBT 221 supplies to a load. The semiconductor element 22 may have a freewheeling diode connected in reverse parallel to the IGBT 221. The semiconductor element 22 contains, for example, a semiconductor chip where the IGBT 221 and the current sensing element 222 are formed.

The semiconductor control circuit 21 provided in the semiconductor device 2 has a switching time adjustment section 211, the drive current adjustment section 212, and a state detection section 213. The semiconductor control circuit 21 is an integrated circuit for driving/protection functions that drives and protects the IGBT 221.

The state detection section 213 detects the operation state of the IGBT 221. The state detection section 213 has a current detection section 213ID detecting the magnitude of the load current IL corresponding to the sensing current Is sensed in the current sensing element 222 as the operation state of the IGBT 221. The current detection section 213ID has a current-to-voltage conversion circuit 213a (one example of the conversion circuit) converting the sensing current Is into a sensing voltage Vs and a buffer circuit 213b outputting the sensing voltage Vs output from the current-to-voltage conversion circuit 213a as a current detection signal Ss having a signal level according to the magnitude of the load current IL.

The current-to-voltage conversion circuit 213a has a resistive element R213. The resistive element R213 has one terminal connected to the sensing signal input terminal Tdi. The resistive element R213 has the other terminal connected to a reference potential terminal (e.g., ground terminal) of the semiconductor control circuit 21. The current-to-voltage conversion circuit 213a outputs, to the buffer circuit 213b, a voltage, which is generated between both the one terminal and the other terminal of the resistive element R213 by the flow of the sensing current Is input from the current sensing element 222, as the sensing voltage Vs. The buffer circuit 213b contains, for example, an operational amplifier. The buffer circuit 213b has a non-inverting input terminal (+) to which the one terminal of the resistive element R213 is connected. The buffer circuit 213b has an inverting input terminal (−) connected to an output terminal of the buffer circuit 213b. Therefore, the buffer circuit 213b functions as a voltage follower circuit and outputs the current detection signal Ss having the same voltage level as that of the sensing voltage Vs.

The switching time adjustment section 211 has a NOT gate 211a, a transistor 211b, the delay time adjustment circuit 211AC, a buffer circuit 211e, and a NOT gate 211f.

The NOT gate 211a has an input terminal connected to the signal input terminal Tic provided in the semiconductor control circuit 21. The NOT gate 211a has an output terminal connected to a transistor 211b. The transistor 211b contains, for example, an N-MOSFET (Metal-Oxide Semiconductor Field Effect Transistor). The transistor 211b has a gate to which the output terminal of the NOT gate 211a is connected. The transistor 211b has a source connected to the reference potential terminal (e.g., ground terminal) of the semiconductor control circuit 21. The transistor 211b has a drain connected to the delay time adjustment circuit 211AC.

The NOT gate 211f has an input terminal to which the output terminal of the buffer circuit 213b is connected. The NOT gate 211f has an output terminal connected to the delay time adjustment circuit 211AC. The NOT gate 211f inverts the signal level of the current detection signal Ss input from the buffer circuit 213b and outputs inverted the current detection signal Ss to the delay time adjustment circuit 211AC.

The delay time adjustment circuit 211AC adjusts a delay time of the input signal Sin input from the outside (e.g., control device (not illustrated) controlling the semiconductor control circuit 21) according to the signal level of the current detection signal Ss input from the current detection section 213ID. The delay time adjustment circuit 211AC has a variable constant current source 211c, a delay time change section 211d, and the buffer circuit 211e.

The variable constant current source 211c operates by a power supply driving the delay time adjustment circuit 211AC. The variable constant current source 211c has a current control terminal to which the output terminal of the NOT gate 211f is connected. The variable constant current source 211c outputs a constant current having a current value varying according to the signal level (e.g., voltage level) of the current detection signal Ss input from the buffer circuit 213b. More specifically, the variable constant current source 211c outputs a constant current having a current value varying according to the signal level (e.g., voltage level) of the current detection signal Ss input from the buffer circuit 213b and inverted in the NOT gate 211f. The variable constant current source 211c, for example, has the same configuration as that of a variable constant current source 212VC provided in the drive current adjustment section 212 described later. The variable constant current source 211c outputs a constant current having a smaller current value the lower the signal level of the inverted signal input from the NOT gate 211f (i.e., the higher the signal level of the current detection signal Ss). The variable constant current source 211c outputs a constant current having a larger current value the higher the signal level of the inverted signal input from the NOT gate 211f (i.e., the lower the signal level of the current detection signal Ss).

The variable constant current source 211c has an output terminal connected to the drain of the transistor 211b and the delay time change section 211d. The delay time change section 211d has a resistive element R211d and a capacitor C211d. The delay time adjustment circuit 211AC adjusts the delay time of the input signal Sin based on the amount of a current input from the variable constant current source 211c into the delay time change section 211d and a time constant determined by the resistance value of the resistive element R211d and the capacitance value of the capacitor C211d. The time constant is a fixed value, and therefore the delay time adjustment circuit 211AC outputs the delayed signal Sdy obtained by delaying the input signal Sin according to the current value of an output current Iout output from the variable constant current source 211c.

The resistive element R211d provided in the delay time change section 211d has one terminal connected to the output terminal of the variable constant current source 211c and the drain of the transistor 211b. The resistive element R211d has the other terminal connected to one electrode of the capacitor C211d. The capacitor C211d has the other electrode connected to the reference potential terminal (e.g., ground terminal) of the semiconductor control circuit 21. The delay time change section 211d has an output terminal (connection part between the other terminal of the resistive element R211d and the one electrode of the capacitor C211d) to which an input terminal of the buffer circuit 211e is connected. The buffer circuit 211e contains, for example, a voltage follower circuit as with the buffer circuit 213b. The buffer circuit 211e has an output terminal connected to an input terminal of the drive current adjustment section 212. Thus, the buffer circuit 211e outputs the delayed signal Sdy input from the delay time change section 211d to the drive current adjustment section 212 without changing the signal level.

The variable constant current source 211c outputs the output current Iout having a smaller current value the higher the signal level (i.e., voltage level) of the current detection signal Ss input from the current detection section 213ID. On the other hand, the variable constant current source 211c outputs the output current Iout having a larger current value the lower the signal level (i.e., voltage level) of the current detection signal Ss input from the current detection section 213ID. In other words, the variable constant current source 211c outputs the output current Iout having a larger current value the smaller the current value of the load current IL that the IGBT 221 supplies to the load device. On the other hand, the variable constant current source 211c outputs the output current Iout having a smaller current value the larger the current value of the load current IL that the IGBT 221 supplies to the load device.

The switch of the signal level of the input signal Sin from a low level to a high level causes the transition from an on-state to an off-state, and therefore the transistor 211b disconnects the output terminal of the variable constant current source 211c from the reference potential terminal. Thus, the output current Iout output from the variable constant current source 211c flows to the delay time change section 211d, so that the delayed signal Sdy output from the delay time change section 211d rises. A rise time of the delayed signal Sdy depends on the current value of the output current Iout output from the variable constant current source 211c, and becomes shorter the larger the current value.

The switch of the signal level of the input signal Sin from a high level to a low level causes the transition from an off-state to an on-state, and therefore the transistor 211b connects the output terminal of the variable constant current source 211c to the reference potential terminal. Thus, the output current Iout output from the variable constant current source 211c flows to the reference potential terminal. Further, the capacitor C211d provided in the delay time change section 211d discharges, so that the delayed signal Sdy output from the delay time change section 211d falls. Charges charged in the capacitor C211d are extracted faster the larger the current amount of the output current Iout flowing from the variable constant current source 211c to the reference potential terminal, shortening the discharge time of the capacitor C211d. Therefore, a fall time of the delayed signal Sdy becomes shorter the larger the current amount. The delay time change section 211d exhibits not only a function of generating the delayed signal Sdy delayed with respect to the input signal Sin but a function of suppressing ringing occurring in the output current Iout output from the variable constant current source 211c.

A timing when the signal level of the input signal Sin is switched is an input timing of the input signal Sin. The drive current adjustment section 212 generates the drive current Idv by the input of the delayed signal Sdy. Accordingly, the delay time is a time from when the input signal Sin is input into the switching time adjustment section 211 until the delayed signal Sdy is output to the drive current adjustment section 212 and the supply of the drive current Idv to the IGBT 221 is started. A timing when the supply of the drive current Idv to the IGBT 221 is started is, for example, a timing when the current value of the collector current (i.e., load current IL) flowing to the IGBT 221 reaches 10% of the target value.

Thus, the switching time adjustment section 211 delays the input signal Sin according to the magnitude of the load current IL detected in the current detection section 213ID. Thus, the switching time adjustment section 211 adjusts the switching time of the IGBT 221 according to the magnitude of the load current IL detected in the current detection section 213ID as the operation state of the IGBT 221. The variable constant current source 211c provided in the delay time adjustment circuit 211AC can successively change the current amount of the output current Iout according to successive variations in the signal level (i.e., voltage level) of the current detection signal Ss input from the current detection section 213ID. Therefore, the switching time adjustment section 211 successively adjusts the switching time according to fluctuations in the sensing current Is.

As illustrated in FIG. 6, the drive current adjustment section 212 has an operational amplifier 212a, transistors 212b, 212c, 212e, 212f, 212g, and a resistive element 212d. The transistor 212c contains, for example, an N-MOSFET. The transistors 212b, 212e, 212f, 212g contain, for example, a P-MOSFET.

The transistor 212e and the transistor 212f constitute a current mirror circuit 212 CM. The transistor 212e has a source connected to a power supply terminal to which a power supply driving the gate drive circuit 212DC is supplied. The transistor 212e has a drain connected to a gate of each of the transistors 212e, 212f and a drain of the transistor 212c.

The transistor 212f has a source connected to the power supply terminal to which the power supply driving the gate drive circuit 212DC is supplied. The transistor 212f has a drain connected to a source of the transistor 212g. The transistor 212g has a drain connected to the reference potential terminal (e.g., ground terminal) of the semiconductor control circuit 21. The transistor 212g has a gate connected to an output terminal of the switching time adjustment section 211 (specifically the output terminal of the buffer circuit 211e). A connection part between the drain of the transistor 212f and the source of the transistor 212g is connected to a current output terminal Toc. The connection part between the drain of the transistor 212f and the source of the transistor 212g serves as an output terminal of the drive current adjustment section 212.

The operational amplifier 212a, the transistors 212b, 212c, and the resistive element 212d constitute the variable constant current source 212VC. A non-inverting input terminal (+) of the operational amplifier 212a serving as a current control terminal of the variable constant current source 212VC is connected to an output terminal of the current detection section 213ID. The operational amplifier 212a has an inverting input terminal (−) connected to a source of the transistor 212c and one terminal of the resistive element 212d. The operational amplifier 212a has an output terminal connected to a gate of the transistor 212c and a source of the transistor 212b. The transistor 212b has a drain connected to the reference potential terminal (e.g., ground terminal) of the semiconductor control circuit 21. The transistor 212b has a gate connected to the output terminal of the switching time adjustment section 211 (specifically the output terminal of the buffer circuit 211e). The resistive element 212d has the other terminal connected to the reference potential terminal (e.g., ground terminal) of the semiconductor control circuit 21.

The variable constant current source 212VC controls the transistor 212c such that a constant current according to the voltage level of the current detection signal Ss input into the non-inverting input terminal (+) of the operational amplifier 212a flows from the current mirror circuit 212 CM.

When the signal level of the delayed signal Sdy input from the switching time adjustment section 211 becomes a high level, the transistor 212b enters an off-state, and therefore the variable constant current source 212VC operates to pass the constant current according to the voltage level of the current detection signal Ss to the transistor 212c. When the signal level of the delayed signal Sdy input from the switching time adjustment section 211 becomes a high level, the transistor 212g enters an off-state, and therefore the current mirror circuit 212 CM outputs, to a gate of the IGBT 221, a current corresponding to the current that the variable constant current source 212VC passes to the transistor 212c as the drive current Idv (i.e., gate current).

The output voltage of the operational amplifier 212a fluctuates according to fluctuations in the voltage level of the current detection signal Ss. Therefore, the drive current Idv fluctuates according to the fluctuations in the voltage level of the current detection signal Ss. The current detection signal Ss is a signal obtained by performing current-to-voltage conversion of the sensing current Is sensed in the current sensing element 222, and therefore fluctuates according to the fluctuations in the sensing current Is. The sensing current Is is a successively varying current. Accordingly, the drive current adjustment section 212 successively adjusts the drive current Idv according to the fluctuations in the sensing current Is.

The voltage level of the current detection signal Ss output from the current detection section 213ID is based on the magnitude of the load current IL that the IGBT 221 supplies to the load device. Therefore, the drive current adjustment section 212 can supply, to the gate of the IGBT 221, the drive current Idv according to the magnitude of the load current IL that the IGBT 221 supplies to the load device. Thus, the drive current adjustment section 212 adjusts the drive current Idv driving the IGBT 221 according to the magnitude of the load current IL detected in the current detection section 213ID as the operation state of the IGBT 221.

Further, the drive current adjustment section 212 starts the supply of the drive current Idv to the IGBT 221 by the input of the delayed signal Sdy from the switching time adjustment section 211. Therefore, the drive current adjustment section 212 supplies, to the IGBT 221, the drive current Idv delayed according to the current value of the load current IL that the IGBT 221 supplies to the load device with respect to the input timing of the input signal Sin. Thus, the drive current adjustment section 212 has a gate drive circuit 212DC (one example of the drive circuit) driving the IGBT 221 by the drive current Idv having a current amount according to the signal level of the current detection signal Ss when the delayed signal Sdy obtained by delaying the input signal Sin is input from the delay time adjustment circuit 211AC.

### 2-2. Operation of Semiconductor Device:

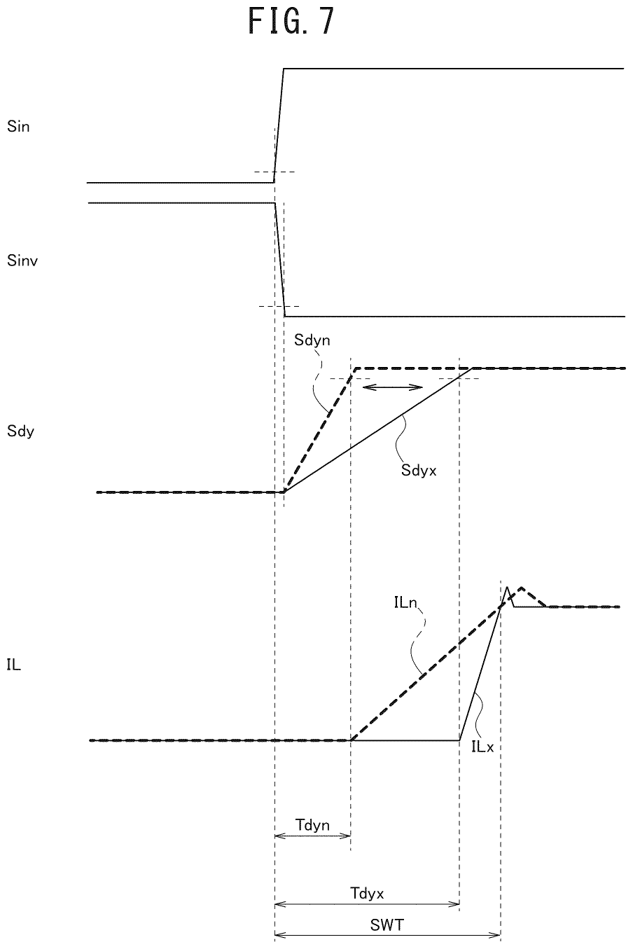

The operation of the semiconductor device 2 according to this embodiment is described using FIG. 7 with reference to FIGS. 5 and 6. FIG. 7 is a timing chart schematically illustrating part of operation waveforms of the semiconductor device 2. “Sin” in FIG. 7 indicates the input signal input into the switching time adjustment section 211. “Sinv” in FIG. 7 indicates an inverted signal output from the NOT gate 211a provided in the switching time adjustment section 211. “Sdy” in FIG. 7 indicates the delayed signal output from the delay time adjustment circuit 211AC. “IL” in FIG. 7 indicates the load current that the IGBT 221 supplies to the load device.

As illustrated in FIG. 7, when the input signal Sin rises, the inverted signal Siny falls. When the voltage level of the inverted signal Sinv becomes lower than the threshold voltage of the transistor 211b, the transistor 211b enters an off-state, and therefore the output current Iout output from the variable constant current source 211c flows to the delay time change section 211d. Thus, the signal level of the delayed signal Sdy rises.

When the load current IL that the IGBT 221 supplies to the load device is the smallest in the suppliable range (i.e., when the target value is the smallest), the signal level of the current detection signal Ss becomes the lowest in the variable range. Therefore, the current amount of the output current Iout output from the variable constant current source 211c provided in the delay time adjustment circuit 211AC becomes the largest in the variable range. Thus, the delayed signal Sdy rises the fastest in the range where it can fluctuate and becomes a signal delayed by a delay time Tdyn with respect to the input signal Sin as illustrated by the waveform Sdyn in FIG. 7. When the voltage level of the delayed signal Sdy is higher than the threshold voltage of the transistors 212b, 212g, the transistors 212b, 212g enter an off-state, and therefore the drive current Idv flows to the gate of the IGBT 221.

The signal level of the current detection signal Ss at this time is the lowest in the variable range, and therefore a current that the variable constant current source 212VC provided in the gate drive circuit 212DC of the drive current adjustment section 212 passes to the transistor 212c becomes the smallest in the variable range. Therefore, the current supply capability of the drive current adjustment section 212 is the lowest, so that a rise time of the load current IL becomes the longest in the fluctuation range as illustrated by a waveform ILn in a lower part in FIG. 7. As a result, the switching time of the IGBT 221 at the time of low current becomes a switching time SWT.

As the load current IL of the IGBT 221 increases, the signal level of the current detection signal Ss becomes higher, and therefore the delayed signal Sdy rises the latest in the range where it can fluctuate and becomes a signal delayed by a delay time Tdyx with respect to the input signal Sin as illustrated by a waveform Sdyx in FIG. 7. The delay time Tdyx is the longest time in the fluctuation range of the delayed signal Sdy.

The signal level of the current detection signal Ss at this time is the highest in the variable range, and therefore a current that the variable constant current source 212VC provided in the gate drive circuit 212DC of the drive current adjustment section 212 passes to the transistor 212c becomes the largest in the variable range. Thus, the current supply capability of the drive current adjustment section 212 is the highest, and therefore the rise time of the load current IL is the shortest in the fluctuation range as illustrated by a waveform ILx in the lower part in FIG. 7. As a result, the switching time of the IGBT 221 at the time of normal current becomes the switching time SWT as with the switching time of the IGBT 221 at the time of low current.

As indicated by the two-way arrows in FIG. 7, the rise time of the delayed signal Sdy successively varies according to successive variations in the load current IL (i.e., successive variations in the signal level of the current detection signal Ss). Therefore, the switching time of the IGBT 221 also successively varies according to successive variations in the load current IL (i.e., successive variations in the signal level of the current detection signal Ss).

As described above, the semiconductor device 2 according to this embodiment includes the IGBT 221, the state detection section 213 detecting the operation state of the IGBT 221, the switching time adjustment section 211 adjusting the switching time of the IGBT 221 according to the operation state detected in the state detection section 213, and the drive current adjustment section 212 adjusting the drive current Idv driving the IGBT 221 according to the operation state detected in the state detection section 213.

The semiconductor device 2 has such a configuration, and therefore can suppress the variations in responsiveness of the switching element even when the driving capability to drive the switching element is changed.

### Third Embodiment

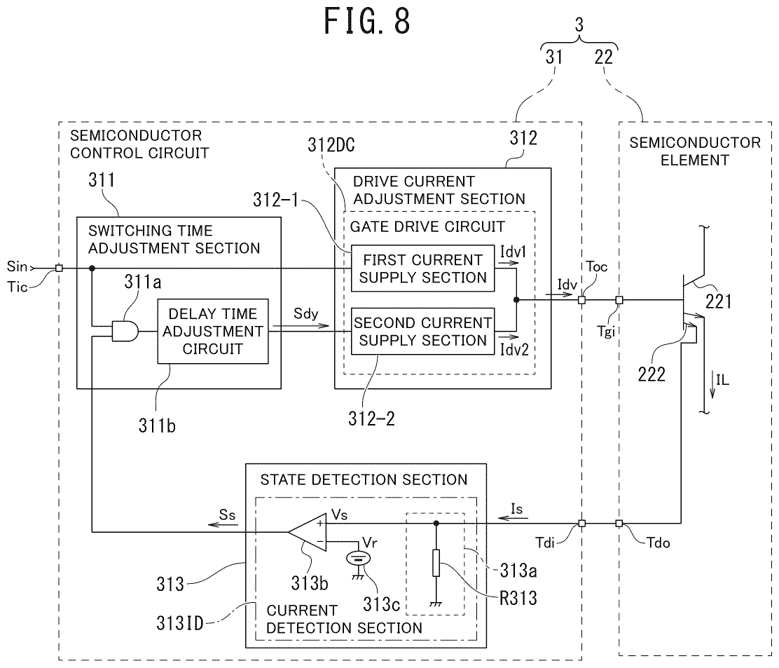

A semiconductor device according to a third embodiment of the present invention is described using FIG. 8. FIG. 8 is a block diagram illustrating one example of the schematic configuration of a semiconductor device 3 according to this embodiment. For the semiconductor device 3 according to this embodiment, the same reference sings are used for constituent elements exhibiting the same operations and functions as those of the constituent elements in the semiconductor device 2 according to the second embodiment above, and descriptions thereof are omitted.

### 3-1. Configuration of Semiconductor Device:

As illustrated in FIG. 8, the semiconductor device 3 according to this embodiment includes a semiconductor control circuit 31 and the semiconductor element 22. The semiconductor control circuit 31 has a switching time adjustment section 311, a drive current adjustment section 312, and a state detection section 313.

The state detection section 313 has a current detection section 313ID detecting the magnitude of the load current IL corresponding to the sensing current Is sensed in the current sensing element 222 as the operation state of the IGBT 221.

The current detection section 313ID has a current-to-voltage conversion circuit 313a (one example of the conversion circuit) converting the sensing current Is into the sensing voltage Vs and a comparator 313b outputting the current detection signal Ss having a signal level based a comparison result obtained by comparing the levels (high or low) of the sensing voltage Vs output from the current-to-voltage conversion circuit 313a and a reference voltage Vr. Further, the current detection section 313ID has a reference voltage generation circuit 313c generating the reference voltage Vr.

The current-to-voltage conversion circuit 313a has a resistive element R313. The current-to-voltage conversion circuit 313a outputs, to the comparator 313b, a voltage, which is generated between both terminals of the resistive element R313 by the flow of the sensing current Is input from the current sensing element 222, as the sensing voltage Vs. The current-to-voltage conversion circuit 313a has the same configuration as that of the current-to-voltage conversion circuit 213a in the second embodiment above, except that the output destination of the sensing voltage Vs is the comparator 313b.

The reference voltage generation circuit 313c contains, for example, a direct-current voltage source. The reference voltage generation circuit 313c has a positive electrode side connected to an input terminal of the comparator 313b. The reference voltage generation circuit 313c has a negative electrode side connected to a reference potential terminal (e.g., ground terminal) of the semiconductor control circuit 31.

The comparator 313b contains, for example, an operational amplifier. The comparator 313b has a non-inverting input terminal (+) connected to an output terminal of the current-to-voltage conversion circuit 313a (specifically one terminal of the resistive element R313). The comparator 313b has an inverting input terminal (−) connected to the positive electrode side of the reference voltage generation circuit 313c. The comparator 313b outputs the current detection signal Ss having a low signal level when the sensing voltage Vs is lower than the reference voltage Vr. On the other hand, the comparator 313b outputs the current detection signal Ss having a high signal level when the sensing voltage Vs is higher than the reference voltage Vr.

The sensing voltage Vs becomes higher the larger the sensing current Is becomes. The sensing current Is becomes larger the larger the load current IL. Accordingly, the comparator 313b outputs the current detection signal Ss having a low signal level when the load current IL is smaller than a current corresponding to the reference voltage Vr. The comparator 313b outputs the current detection signal Ss having a high signal level when the load current IL is larger than the current corresponding to the reference voltage Vr. The current corresponding to the reference voltage Vr is a current serving as the boundary separating the current at the time of low current and the current at the time of normal current described in the first embodiment above. For example, the current corresponding to the reference voltage Vr is a current having a 15% current amount of the rated current of the IGBT 221.

The switching time adjustment section 311 has an AND gate 311a and a delay time adjustment circuit 311b.

The AND gate 311a has one input terminal connected to the signal input terminal Tic provided in the semiconductor control circuit 31. The AND gate 311a has the other input terminal connected to an output terminal of the state detection section 313 (more specifically, output terminal of the comparator 313b). The AND gate 311a outputs, to the delay time adjustment circuit 311b, an arithmetic signal obtained by performing a logical multiplication operation of the signal level of the input signal Sin input via the signal input terminal Tic and the signal level of the current detection signal Ss output from the comparator 313b.

The delay time adjustment circuit 311b provided in the switching time adjustment section 311 adjusts the delay time of the input signal Sin input from the outside (e.g., control device (not illustrated) controlling the semiconductor control circuit 31) according to the signal level of the current detection signal Ss input from the comparator 313b.

The AND gate 311a outputs an arithmetic signal having a signal level constant at a low level to the delay time adjustment circuit 311b when the current detection signal Ss has a low signal level and outputs the input signal Sin to the delay time adjustment circuit 311b when the current detection signal Ss has a high signal level. The signal level of the current detection signal Ss output from the comparator 313b becomes a high level when the load current IL is large (when the target value of the load current IL is a current value at the time of normal current as described in the first embodiment above). Therefore, the input signal Sin is input into the delay time adjustment circuit 311b when the load current IL is large. On the other hand, the arithmetic signal having a signal level constant at a low level is input into the delay time adjustment circuit 311b when the load current IL is small (when the target value of the load current IL is a current value at the time of low current as described in the first embodiment above). Therefore, the delay time adjustment circuit 311b outputs the delayed signal Sdy obtained by delaying the input signal Sin when the load current IL is large and outputs the arithmetic signal having a signal level constant at a low level as it is when the load current IL is small.

The drive current adjustment section 312 has a gate drive circuit 312DC. The gate drive circuit 312DC (one example of the drive circuit) drives the IGBT 221 by the drive current Idv having a current amount according to the signal level of the current detection signal Ss when the delayed signal Sdy obtained by delaying the input signal Sin is input from the delay time adjustment circuit 311b. The gate drive circuit 312DC has a plurality of current supply sections (first current supply section 312-1 and second current supply section 312-2) selectively supplying the drive current Idv to the IGBT 221 according to the signal level of the current detection signal Ss.

As illustrated in FIG. 8, the first current supply section 312-1 provided in the gate drive circuit 312DC is selected and supplies a drive current Idv1 to the IGBT 221 at least when the current detection signal Ss has a signal level indicating that the sensing voltage Vs is lower than the reference voltage Vr. In this embodiment, the input signal Sin is input into the first current supply section 312-1 but the current detection signal Ss is not input into the first current supply section 312-1. Therefore, the first current supply section 312-1 starts the supply of the drive current Idv1 to the IGBT 221 with the input of the input signal Sin as a trigger. On the other hand, the first current supply section 312-1 supplies the drive current Idv1 to the IGBT 221 even when the current detection signal Ss has a signal level indicating that the sensing voltage Vs is higher than the reference voltage Vr besides the case where the current detection signal Ss has the signal level indicating that the sensing voltage Vs is lower than the reference voltage Vr.

The second current supply section 312-2 is selected and supplies a drive current Idv2 to the IGBT 221 when the current detection signal Ss has the signal level indicating that the sensing voltage Vs is higher than the reference voltage Vr. More specifically, when the current detection signal Ss has the signal level indicating that the sensing voltage Vs is higher than the reference voltage Vr, the IGBT 221 supplies the load current IL having a large target value (load current at the time of normal current as described in the first embodiment above) to the load device. Therefore, the second current supply section 312-2 outputs the drive current Idv2 to the gate of the IGBT 221 so that the IGBT 221 can supply the load current IL having a large target value to the load device.

The first current supply section 312-1 supplies the drive current Idv1 to the gate of the IGBT 221 when the input signal Sin is input. The second current supply section 312-2 supplies the drive current Idv2 to the gate of the IGBT 221 when the delayed signal Sdy is input. The gate of the IGBT 221 is supplied with the drive current Idv obtained by combining the drive current Idv1 and the drive current Idv2.

In this embodiment, for example, the second current supply section 312-2 supplies the drive current Idv2 having a current value larger than that of the first current supply section 312-1 to the IGBT 221. Therefore, a turn-on time of the IGBT 221 becomes shorter when the drive current Idv2 is supplied than when the drive current Idv1 is supplied. The first current supply section 312-1 supplies the drive current Idv1 to the IGBT 221 based on the input of the input signal Sin. In contrast thereto, the second current supply section 312-2 supplies the drive current Idv2 to the IGBT 221 based on the input of the delayed signal Sdy, the delay time of which has been adjusted in the delay time adjustment circuit 311b of the switching time adjustment section 311. Therefore, a timing when the IGBT 221 starts turn-on is delayed when the drive current Idv2 is supplied as compared with the timing when the drive current Idv1 is supplied. As a result, the switching time of the IGBT 221 when the drive current Idv1 is supplied as the drive current Idv to the gate of the IGBT 221 and the switching time of the IGBT 221 when the drive current Idv obtained by combining the drive current Idv1 and the drive current Idv2 is supplied to the gate of the IGBT 221 are substantially the same. This allows the semiconductor device 3 to suppress the variations in responsiveness of the IGBT 221 when the driving capability to drive the IGBT 221 is only the drive current Idv1 and when the driving capability to drive the IGBT 221 is a combination of the drive currents Idv1, Idv2.

### 3-2. Operation of Semiconductor Device:

The operation of the semiconductor device 3 according to this embodiment is described using FIGS. 4 and 8. The operation of the semiconductor device 3 according to this embodiment is described taking the time when the IGBT 221 is turned on as an example.

When the IGBT 221 supplies the load current IL having a small target value (load current at the time of low current described in the first embodiment above) to the load device, the sensing voltage Vs is lower than the reference voltage Vr. Therefore, when the input signal Sin is input into the semiconductor control circuit 31, the first current supply section 312-1 supplies the drive current Idv1 to the gate of the IGBT 221, whereas the second current supply section 312-2 does not supply the drive current Idv2 to the gate of the IGBT 221. Thus, the switching time of the IGBT 221 becomes the switching time ton0 as illustrated in the upper part in FIG. 4.

When the IGBT 221 supplies the load current IL having a large target value (load current at the time of normal current as described in the first embodiment above) to the load device, the sensing voltage Vs is higher than the reference voltage Vr. Therefore, when the input signal Sin is input into the semiconductor control circuit 31, the delayed signal Sdy is output from the delay time adjustment circuit 311b to the second current supply section 312-2. Therefore, the first current supply section 312-1 supplies the drive current Idv1 to the gate of the IGBT 221 and the second current supply section 312-2 supplies the drive current Idv2 to the gate of the IGBT 221. Thus, as illustrated in the lower part in FIG. 4, the turn-on time of the IGBT 221 is shortened, but a timing when the load current IL (i.e., collector current of the IGBT 221) starts to flow is delayed by the delay time Tdy of the delayed signal Sdy with respect to the input signal Sin, and therefore the switching time of the IGBT 221 becomes the switching time ton0.

Thus, the semiconductor device 3 can suppress the variations in responsiveness of the IGBT 221 due to the current amount of the load current IL of the IGBT 221.

As described above, the semiconductor device 3 according to this embodiment includes the IGBT 221, the state detection section 313 detecting the operation state of the IGBT 221, the switching time adjustment section 311 adjusting the switching time of the IGBT 221 according to the operation state detected in the state detection section 313, and the drive current adjustment section 312 adjusting the drive current Idv driving the IGBT 221 according to the operation state detected in the state detection section 313.

The semiconductor device 3 has such a configuration, and therefore can suppress the variations in responsiveness of the switching element even when the driving capability to drive the switching element is changed.

### Fourth Embodiment

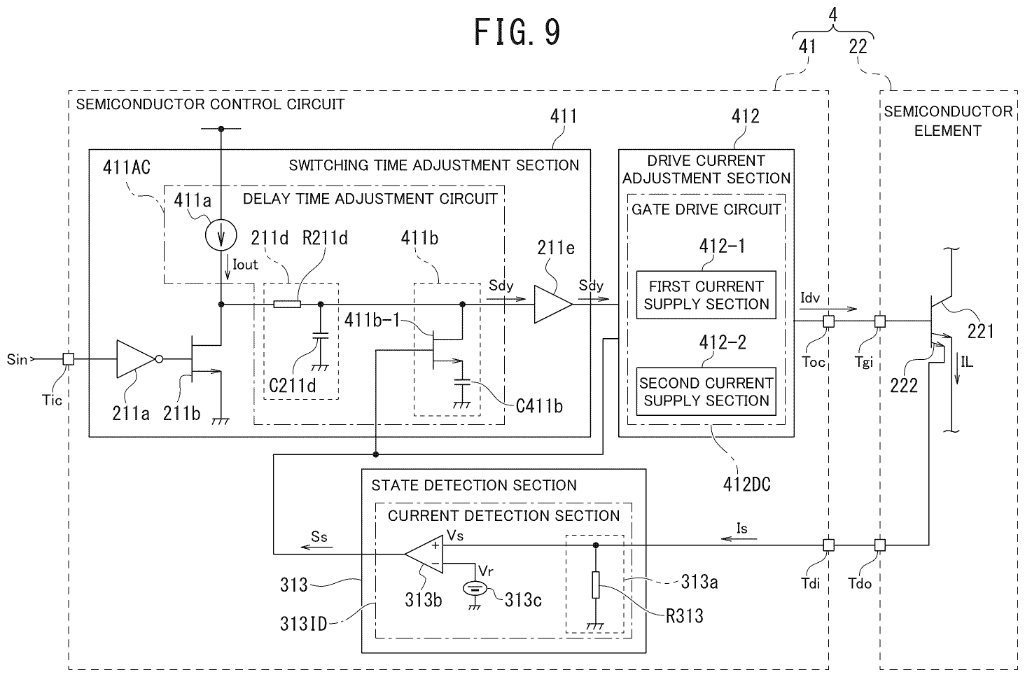

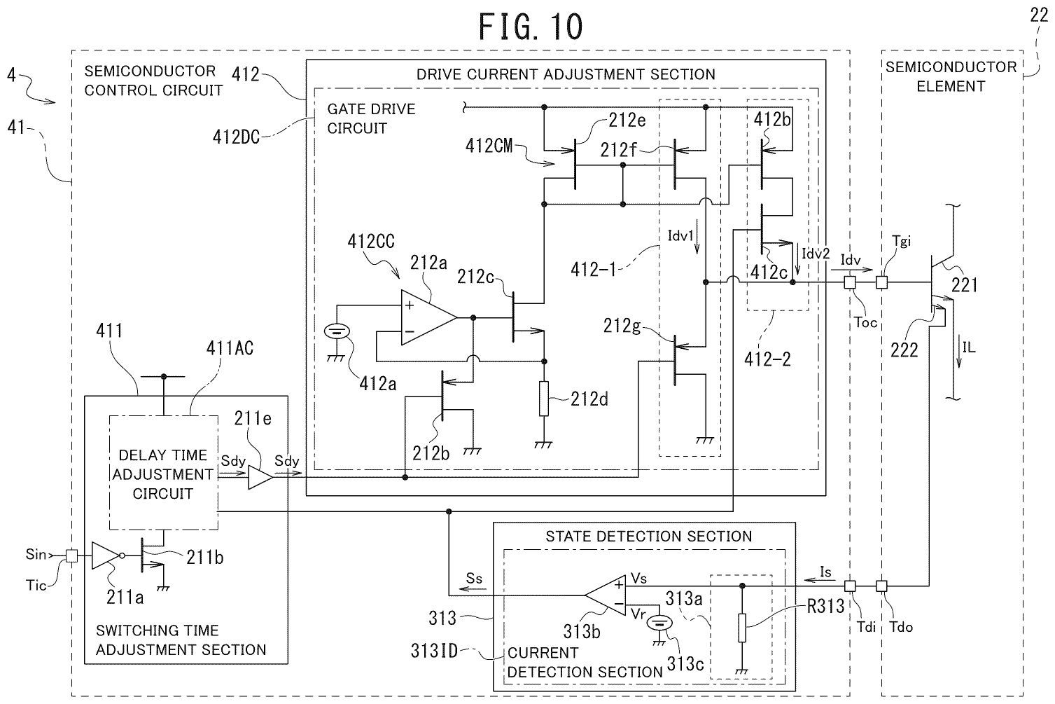

A semiconductor device according to a fourth embodiment of the present invention is described using FIGS. 9 to 11. FIGS. 9 and 10 are block diagrams illustrating one example of the schematic configuration of a semiconductor device 4 according to this embodiment. FIG. 9 does not illustrate the specific configuration of a drive current adjustment section 412. FIG. 10 does not illustrate the specific configuration of a delay time adjustment circuit 411AC. For the semiconductor device 4 according to this embodiment, the same reference sings are used for constituent elements exhibiting the same operations and functions as those of the constituent elements in the semiconductor devices 1, 2, 3 according to the first to third embodiments above, respectively, and descriptions thereof are omitted.

### 4-1. Configuration of Semiconductor Device:

As illustrated in FIGS. 9 and 10, the semiconductor device 4 according to this embodiment includes a semiconductor control circuit 41 and the semiconductor element 22. The semiconductor control circuit 41 has a switching time adjustment section 411, the drive current adjustment section 412, and the state detection section 313. The state detection section 313 has the current detection section 313ID. The state detection section 313 and the current detection section 313ID in this embodiment have the same configurations as those of the state detection section 313 and the current detection section 313ID, respectively, in the third embodiment above. The voltage value of the reference voltage Vr in this embodiment may be set to the same value as the voltage value of the reference voltage Vr in the third embodiment above or may be set to a different value.

The switching time adjustment section 411 has the NOT gate 211a, the transistor 211b, the delay time adjustment circuit 411AC, and the buffer circuit 211e. The delay time adjustment circuit 411AC has a constant current source 411a and the delay time change section 211d, a delay time change section 411b.

The delay time change section 411b has a transistor 411b-1 and a capacitor C411b. The transistor 411b-1 contains, for example, an N-MOSFET. The transistor 411b-1 has a gate connected to the output terminal of the comparator 313b provided in the current detection section 313ID. Thus, in the transistor 411b-1, an on/off state is controlled by the signal level of the current detection signal Ss input from the comparator 313b.

The delay time change section 411b is connected between the delay time change section 211d and the buffer circuit 211e. The capacitor C411b is arranged in parallel to the capacitor C211d on the downstream side of the delay time change section 211d. The capacitor C411b is disconnected from wiring between the capacitor C211d and the buffer circuit 211e when the transistor 411b-1 is in an off-state. On the other hand, the capacitor C411b is connected in parallel to the capacitor C211d when the transistor 411b-1 is in an on-state. Thus, the capacitance of a capacitor formed between wiring from an output terminal of the constant current source 411a to the buffer circuit 211e and the reference potential terminal (e.g., ground terminal) of the semiconductor control circuit 41 increases by the capacitance of the capacitor C411b when the transistor 411b-1 enters an on-state.

The constant current source 411a operates by a power supply driving the delay time adjustment circuit 411AC. The constant current source 411a has an output terminal connected to the drain of the transistor 211b and the delay time change section 211d. Therefore, the output current Iout output from the constant current source 411a flows to the reference potential terminal (e.g., ground terminal) of the semiconductor control circuit 41 when the input signal Sin has a low signal level and hardly flows to the delay time change section 211d. On the other hand, the output current Iout output from the constant current source 411a hardly flow to the reference potential terminal of the semiconductor control circuit 41 and flows to the delay time change section 211d when the input signal Sin has a high signal level.

In the semiconductor device 4, the current amount of the output current Iout output from the constant current source 411a is constant unlike the semiconductor device 2 according to the second embodiment above. Therefore, the rise time of the delayed signal Sdy is delayed by the capacitance of the capacitor C411b when the transistor 411b-1 is in an on-state as compared with the rise time when the transistor 411b-1 is in an off-state. The on/off state of the transistor 411b-1 is controlled by the current detection signal Ss. In other words, the on/off state of the transistor 411b-1 is controlled by the fluctuations in the sensing current Is. When the transistor 411b-1 is in an off-state, the charging target of the output current Iout output from the constant current source 411a includes the capacitor C211d. On the other hand, when the transistor 411b-1 is in an on-state, the charging target of the output current Iout output from the constant current source 411a includes the capacitors C211d, C411b. Therefore, the delayed signal Sdy is more difficult to rise when the transistor 411b-1 is in an on-state than in an off-state, and therefore the delay time is prolonged.

Thus, the delay time adjustment circuit 411AC can change the delay time of the delayed signal Sdy in a stepwise manner by controlling the transistor 411b-1 from an off-state to an on-state or vice versa according to the fluctuations in the sensing current Is. Accordingly, the switching time adjustment section 411 adjusts the switching time of the IGBT 221 in a stepwise manner according to the fluctuations in the sensing current Is.

The on/off state of the transistor 411b-1 is controlled according to the current amount of the load current IL that the IGBT 221 supplies to the load device (not illustrated). Accordingly, the delay time change section 411b can selectively output the delayed signal Sdy obtained by delaying the input signal Sin by a delay time different in length according to the current amount of the load current IL.

Thus, the delay time adjustment circuit 411AC adjusts the delay time of the input signal Sin input from the outside (e.g., control device (not illustrated) controlling the semiconductor control circuit 41) according to the signal level of the current detection signal Ss input from the comparator 313b.

As illustrated in FIG. 10, the drive current adjustment section 412 has a gate drive circuit 412DC. The gate drive circuit 412DC has a constant current source 412CC, a current mirror circuit 412 CM, a first current supply section 412-1, and a second current supply section 412-2. Thus, the gate drive circuit 412DC has a plurality of current supply sections, and the plurality of current supply sections includes the first current supply section 412-1 and the second current supply section 412-2.

The constant current source 412CC has the operational amplifier 212a, the transistor 212b, the transistor 212c, the resistive element 212d, and a direct-current voltage generation section 412a. Thus, the constant current source 412CC has the direct-current voltage generation section 412a unlike the variable constant current source 212VC in the second embodiment above. The direct-current voltage generation section 412a contains, for example, a direct-current voltage source and has a positive electrode side connected to the non-inverting input terminal (+) of the operational amplifier 212a. Therefore, the operational amplifier 212a outputs an output voltage having substantially the same voltage value as that of a voltage generated in the direct-current voltage generation section 412a to the gate of the transistor 212c. This allows the constant current source 412CC to pass a constant current according to the voltage value of the output voltage of the operational amplifier 212a to the transistor 212e of the current mirror circuit 412 CM.

The current mirror circuit 412 CM has the transistor 212e, the transistor 212f, and a transistor 412b. In the semiconductor device 4, the transistor 212f and the transistor 412b have transistor sizes different in magnitude from each other such that the transistor 412b can pass a current having a current amount larger than that of the transistor 212f. The transistor 212f is also a transistor constituting the first current supply section 412-1. The transistor 412b is also a transistor constituting the second current supply section 412-2.

The first current supply section 412-1 has the transistor 212f and the transistor 212g. The transistors 212f, 212g in this embodiment operate in the same manner as the transistors 212f, 212g, respectively, in the second embodiment above. Therefore, the first current supply section 412-1 supplies the drive current Idv1 to the gate of the IGBT 221 when the delayed signal Sdy having a high signal level is input into the transistor 212g from the switching time adjustment section 411. On the other hand, the first current supply section 412-1 passes the drive current Idv1 to the reference potential terminal (e.g., ground terminal) of the semiconductor control circuit 41 instead of supplying the drive current Idv1 to the gate of the IGBT 221 when the delayed signal Sdy having a low signal level is input into the transistor 212g from the switching time adjustment section 411.

Whether the first current supply section 412-1 supplies the drive current Idv1 to the gate of the IGBT 221 is controlled by the signal level of the delayed signal Sdy (i.e., signal level of the input signal Sin) and is not controlled by the signal level of the current detection signal Ss. The first current supply section 412-1 is selected and supplies the drive current Idv1 to the IGBT 221 at least when the current detection signal Ss has the signal level indicating that the sensing voltage Vs is lower than the reference voltage Vr. Further, the first current supply section 412-1 supplies the drive current Idv1 to the IGBT 221 even when the current detection signal Ss has a signal level indicating that the sensing voltage Vs is higher than the reference voltage Vr. The current detection signal Ss indicates that the sensing voltage Vs is lower than the reference voltage Vr by the low signal level and indicates that the sensing voltage Vs is higher than the reference voltage Vr by the high signal level.

The second current supply section 412-2 has the transistor 412b and a transistor 412c. The transistor 412b contains, for example, a P-MOSFET. The transistor 412c contains, for example, an N-MOSFET. The transistor 412b and the transistor 412c are connected in series between a power supply terminal supplied with a power supply driving the gate drive circuit 412DC and the current output terminal Toc provided in the semiconductor control circuit 41. The transistor 412c has a source connected to the current output terminal Toc and a connection part between the transistor 212f and the transistor 212g (i.e., output terminal of the drive current Idv1). The transistor 412c has a gate connected to the output terminal of the comparator 313b.

Therefore, the second current supply section 412-2 supplies the drive current Idv2 to the gate of the IGBT 221 when the current detection signal Ss having a high signal level is input into the transistor 412c from the current detection section 313ID. On the other hand, the second current supply section 412-2 passes the drive current Idv2 to the reference potential terminal (e.g., ground terminal) of the semiconductor control circuit 41 instead of supplying the drive current Idv2 to the gate of the IGBT 221 when the current detection signal Ss having a low signal level is input into the transistor 412c from the current detection section 313ID.

Thus, the on/off state of the second current supply section 412-2 is controlled by the signal level of the current detection signal Ss. Accordingly, the second current supply section 412-2 is selected and supplies the drive current Idv2 to the IGBT 221 when the current detection signal Ss has a signal level indicating that the sensing voltage Vs is higher than the reference voltage Vr.

The first current supply section 412-1 supplies the drive current Idv1 to the IGBT 221 irrespective of the level (high or low) relation between the reference voltage Vr and the sensing voltage Vs, whereas the second current supply section 412-2 supplies the drive current Idv2 to the IGBT 221 only when the sensing voltage Vs is higher than the reference voltage Vr. More specifically, the gate drive circuit 412DC selects only the first current supply section 412-1 when the sensing voltage Vs is lower than the reference voltage Vr (when the current detection signal Ss has a low signal level). The gate drive circuit 412DC selects both the first current supply section 412-1 and the second current supply section 412-2 when the sensing voltage Vs is higher than the reference voltage Vr (when the current detection signal Ss has a high signal level). The gate drive circuit 412DC supplies a current obtained by combining the drive current Idv1 and the drive current Idv2 as the drive current Idv to the gate of the IGBT 221. Therefore, the gate drive circuit 412DC has a plurality of current supply sections (i.e., the first current supply section 412-1 and the second current supply section 412-2) selectively supplying the drive current Idv to the IGBT 221 according to the signal level of the current detection signal Ss.

The drive current adjustment section 412 supplies the drive current Idv to the gate of the IGBT 221 with only the first current supply section 412-1 or supplies the drive current Idv to the gate of the IGBT 221 with both the first current supply section 412-1 and the second current supply section 412-2 according to fluctuations in the level (high or low) of the reference voltage Vr and the sensing voltage Vs, i.e., fluctuations in the sensing current Is. Accordingly, the drive current adjustment section 412 adjusts the drive current Idv in a stepwise manner according to the fluctuations in the sensing current Is.

In this embodiment, for example, the second current supply section 412-2 supplies the drive current Idv2 having a current value larger than that of the first current supply section 412-1 to the IGBT 221. Therefore, the turn-on time of the IGBT 221 is shorter when the drive current Idv2 is supplied to the IGBT 221 than when the drive current Idv1 is supplied to the IGBT 221.

As described above, the drive current adjustment section 412 has the gate drive circuit 412DC driving the IGBT 221 by the drive current Idv having a current amount according to the signal level of the current detection signal Ss when the delayed signal Sdy obtained by delaying the input signal Sin is input from the delay time adjustment circuit 411AC. The delayed signal Sdy becomes a signal having a longer delay time with respect to the input signal Sin when the current detection signal Ss has a high signal level than when the current detection signal Ss has a low signal level. Therefore, the delay time of the delayed signal Sdy input into the gate drive circuit 412DC is longer when the first current supply section 412-1 and the second current supply section 412-2 supply the drive current Idv to the IGBT 221 than when only the first current supply section 412-1 supplies the drive current Idv to the IGBT 221.

Thus, the switching time of the IGBT 221 when the drive current Idv1 is supplied as the drive current Idv to the gate of the IGBT 221 and the switching time of the IGBT 221 when the drive current Idv obtained by combining the drive current Idv1 and the drive current Idv2 is supplied to the gate of the IGBT 221 are substantially the same. This allows the semiconductor device 4 to suppress the variations in responsiveness of the IGBT 221 when the driving capability to drive the IGBT 221 is only the drive current Idv1 and when the driving capability to drive the IGBT 221 is a combination of the drive currents Idv1, Idv2.

### 4-2. Operation of Semiconductor Device:

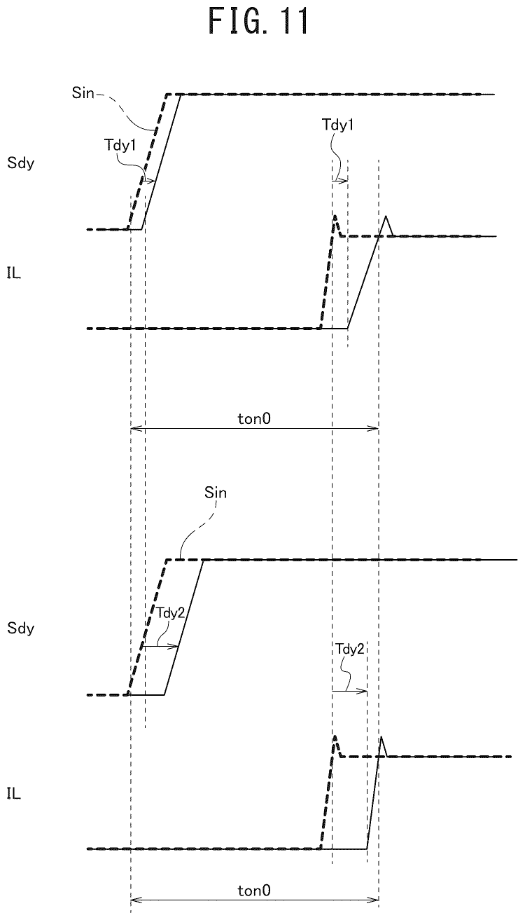

The operation of the semiconductor device 4 according to this embodiment is described using FIG. 11 with reference to FIGS. 9 and 10. FIG. 11 is a timing chart schematically illustrating part of operation waveforms of the semiconductor device 4. “Sdy” in FIG. 11 indicates the delayed signal output from the delay time adjustment circuit 411AC. “Sin” in FIG. 11 indicates the input signal input into the switching time adjustment section 411. “IL” in FIG. 11 indicates the load current that the IGBT 221 supplies to the load device.

When the IGBT 221 supplies the load current IL having a small target value (load current at the time of low current described in the first embodiment above) to the load device, the sensing voltage Vs is lower than the reference voltage Vr. Therefore, when the delayed signal Sdy delayed by a delay time Tdy1 with respect to the input signal Sin is input into the drive current adjustment section 412, the first current supply section 412-1 supplies the drive current Idv1 to the gate of the IGBT 221, whereas the second current supply section 412-2 does not supply the drive current Idv2 to the gate of the IGBT 221. Thus, the switching time of the IGBT 221 becomes the switching time ton0 as illustrated in an upper part in FIG. 11.

When the IGBT 221 supplies the load current IL having a large target value (load current at the time of normal current as described in the first embodiment above) to the load device, the sensing voltage Vs is higher than the reference voltage Vr. Therefore, when the delayed signal Sdy delayed by a delay time Tdy2 longer than that at the time of low current with respect to the input signal Sin is input into the drive current adjustment section 412, the first current supply section 412-1 starts the supply of the drive current Idv1 to the IGBT 221 at a timing later than a timing at the time of low current. When the sensing voltage Vs is higher than the reference voltage Vr, the transistor 412c enters an on-state, and therefore the second current supply section 412-2 also starts the supply of the drive current Idv2. Thus, the turn-on time of the IGBT 221 is shorter than that at the time of low current. As a result, the switching time of the IGBT 221 becomes the switching time ton0 as with the switching time of the IGBT 221 at the time of low current as illustrated in a lower part in FIG. 11.

Thus, the semiconductor device 4 can suppress the variations in responsiveness of the IGBT 221 due to the current amount of the load current IL of the IGBT 221.

As described above, the semiconductor device 4 according to this embodiment includes the IGBT 221, the state detection section 313 detecting the operation state of the IGBT 221, the switching time adjustment section 411 adjusting the switching time of the IGBT 221 according to the operation state detected in the state detection section 313, and the drive current adjustment section 412 adjusting the drive current Idv driving the IGBT 221 according to the operation state detected in the state detection section 313.

The semiconductor device 4 has such a configuration, and therefore can suppress the variations in responsiveness of the switching element even when the driving capability to drive the switching element is changed.

The present invention can be variously modified without being limited to the embodiments above.

The semiconductor devices 1, 2, 3, 4, according to the first embodiment to the fourth embodiment above, respectively, are described taking the time when the IGBT is turned on as an example but the present invention is not limited thereto. The semiconductor devices 1, 2, 3, 4 achieve the same advantageous effects also when the IGBT is turned off.

The semiconductor devices 3, 4 according to the third embodiment and the fourth embodiment above, respectively, can change the drive current Idv supplied to the gate of the IGBT 221 in two stages but can changes the drive current Idv in three or more stages by being provided with a predetermined number of current detection sections and current supply sections.

The semiconductor devices 3, 4 according to the third embodiment and the fourth embodiment above, respectively, are configured so that the drive current Idv1 is supplied from the first current supply sections 312-1, 412-1, respectively, to the gate of the IGBT 221 also at the time of normal current, but the present invention is not limited thereto. The first current supply sections 312-1, 412-1 may be configured so that no current is supplied to the gate of the IGBT 221 at the time of normal current. In this case, the second current supply sections 312-2, 412-2 are required to be configured to supply the drive current Idv2 having a current amount larger than that of the first current supply sections 312-1, 412-1, respectively, to the gate of the IGBT 221.

The technical scope of the present invention is not limited to the illustrated and described exemplary embodiments and also includes all embodiments producing advantageous effects equivalent to the advantageous effects targeted by the present invention. Further, the technical scope of the present invention is not limited to combinations of the features of the invention defined by each claim and can be defined by any desired combination of specific features of all the disclosed features.

### REFERENCE SIGNS LIST

1, 2, 3, 4: semiconductor device
11, 21, 31, 41: semiconductor control circuit
12, 22: semiconductor element
111, 211, 311, 411: switching time adjustment section
112, 212, 312, 412: drive current adjustment section
113, 213, 313: state detection section
121, 221: IGBT
122: state sensing element
211AC, 311b, 411AC: delay time adjustment circuit
211c, 212VC: variable constant current source
211d, 411b: delay time change section
211e, 213b: buffer circuit
212 CM, 412 CM: current mirror circuit
212DC, 312DC, 412DC: gate drive circuit
213a, 313a: current-to-voltage conversion circuit
213ID, 313ID: current detection section
222: current sensing element
311a: AND gate
312-1, 412-1: first current supply section
312-2, 412-2: second current supply section
313b: comparator
313c: reference voltage generation circuit
Idv, Idv1, Idv2: drive current
IL: load current
Is: sensing current
Sin: input signal
Sos: sensing signal
Sosd: state detection signal
Ss: current detection signal
Vr: reference voltage
Vs: sensing voltage

1. A semiconductor device comprising:
a switching element;
a state detection section configured to detect an operation state of the switching element;
a switching time adjustment section configured to adjust a switching time of the switching element according to the operation state detected in the state detection section; and
a drive current adjustment section configured to adjust a drive current driving the switching element according to the operation state detected in the state detection section.

2. The semiconductor device according to claim 1 comprising:
a current sensing element configured to sense a sensing current for detecting a load current that the switching element supplies to a load, wherein
the state detection section has a current detection section configured to detect a magnitude of the load current corresponding to the sensing current sensed in the current sensing element as the operation state,
the switching time adjustment section is configured to adjust a switching time of the switching element according to the magnitude of the load current detected in the current detection section as the operation state, and
the drive current adjustment section is configured to adjust a drive current driving the switching element according to the magnitude of the load current detected in the current detection section as the operation state.

3. The semiconductor device according to claim 2, wherein
the switching time adjustment section is configured to successively adjust the switching time according to a fluctuation in the sensing current, and
the drive current adjustment section is configured to successively adjust the drive current according to the fluctuation in the sensing current.

4. The semiconductor device according to claim 2, wherein
the current detection section has:
a conversion circuit configured to convert the sensing current into a sensing voltage; and
a buffer circuit configured to output the sensing voltage output from the conversion circuit as a current detection signal having a signal level according to the magnitude of the load current,
the switching time adjustment section has a delay time adjustment circuit configured to adjust a delay time of an input signal input from an outside according to the signal level of the current detection signal input from the current detection section, and
the drive current adjustment section has a drive circuit configured to drive the switching element by the drive current having a current amount according to the signal level of the current detection signal when a delayed signal obtained by delaying the input signal is input from the delay time adjustment circuit.

5. The semiconductor device according to claim 2, wherein
the switching time adjustment section is configured to adjust the switching time in a stepwise manner according to a fluctuation in the sensing current, and
the drive current adjustment section is configured to adjust the drive current in a stepwise manner according to the fluctuation in the sensing current.

6. The semiconductor device according to claim 2, wherein
the current detection section has:
a conversion circuit configured to convert the sensing current into a sensing voltage; and
a comparator configured to output a current detection signal having a signal level based on a comparison result obtained by comparing levels (high or low) of the sensing voltage output from the conversion circuit and a reference voltage,
the switching time adjustment section has a delay time adjustment circuit configured to adjust a delay time of an input signal input from an outside according to the signal level of the current detection signal input from the comparator, and
the drive current adjustment section has a drive circuit configured to drive the switching element by the drive current having a current amount according to the signal level of the current detection signal when a delayed signal obtained by delaying the input signal is input from the delay time adjustment circuit.

7. The semiconductor device according to claim 6, wherein the drive circuit has a plurality of current supply sections configured to selectively supply the drive current to the switching element according to the signal level of the current detection signal.

8. The semiconductor device according to claim 7, wherein
the plurality of current supply sections has:
a first current supply section configured to be selected and supply the drive current to the switching element at least when the current detection signal has a signal level indicating that the sensing voltage is lower than the reference voltage; and
a second current supply section configured to be selected and supply the drive current to the switching element when the current detection signal has a signal level indicating that the sensing voltage is higher than the reference voltage.

9. The semiconductor device according to claim 8, wherein the first current supply section is configured to supply the drive current to the switching element even when the current detection signal has the signal level indicating that the sensing voltage is higher than the reference voltage.

10. The semiconductor device according to claim 9, wherein the second current supply section is configured to supply the drive current having a current value larger than a current value of the first current supply section to the switching element.

11. The semiconductor device according to claim 3, wherein
the current detection section has:
a conversion circuit configured to convert the sensing current into a sensing voltage; and
a buffer circuit configured to output the sensing voltage output from the conversion circuit as a current detection signal having a signal level according to the magnitude of the load current,
the switching time adjustment section has a delay time adjustment circuit configured to adjust a delay time of an input signal input from an outside according to the signal level of the current detection signal input from the current detection section, and
the drive current adjustment section has a drive circuit configured to drive the switching element by the drive current having a current amount according to the signal level of the current detection signal when a delayed signal obtained by delaying the input signal is input from the delay time adjustment circuit.

12. The semiconductor device according to claim 5, wherein
the current detection section has:
a conversion circuit configured to convert the sensing current into a sensing voltage; and
a comparator configured to output a current detection signal having a signal level based on a comparison result obtained by comparing levels (high or low) of the sensing voltage output from the conversion circuit and a reference voltage,
the switching time adjustment section has a delay time adjustment circuit configured to adjust a delay time of an input signal input from an outside according to the signal level of the current detection signal input from the comparator, and
the drive current adjustment section has a drive circuit configured to drive the switching element by the drive current having a current amount according to the signal level of the current detection signal when a delayed signal obtained by delaying the input signal is input from the delay time adjustment circuit.
